(19) United States
(12) Patent Application Publication
(10) Pub. No.: US 2016/0197608 A1
(43) Pub. Date: Jul. 7, 2016

(54) MULTI-STAGE SWITCH

(71) Applicant: Johnson Electric S.A., Murten (CH)

(72) Inventors: Alan Roger MOREY, Shanklin (GB); Jean-Francois ROY, Jouarre (FR); Kenneth Arthur SENIOR, Newport (GB)

(21) Appl. No.: 14/990,211

(22) Filed: Jan. 7, 2016

(30) Foreign Application Priority Data
Jan. 7, 2015 (GB) 1500205.8

(51) Int. Cl. H03K 17/96; H01H 59/00

(52) U.S. Cl. CPC H03K 17/962; H01H 59/00; H01H 2215/004; H01H 2231/026; H03K 2217/96

(57) ABSTRACT

A multi-stage switch has a touch-detection layer; a switch circuit substrate; and an electrical contact set including a first electrical contact in communication with the touch-detection layer, and a second electrical contact in communication with the switch circuit substrate. The switch is activatable only upon detection of a touch at the touch-detection layer at or adjacent the first electrical contact and upon electrical activation of the electrical contact set. A method of preventing or inhibiting unintentional activation of the switch and a motor vehicle incorporating the switch is also provided.

### CROSS REFERENCE TO RELATED APPLICATIONS

This non-provisional patent application claims priority under 35 U.S.C. §119(a) from Patent Application No. GB1500205.8 filed in The United Kingdom on Jan. 7, 2015, the entire contents of which are hereby incorporated by reference.

### FIELD OF THE INVENTION

The present invention relates to a multi-stage switch, particularly for a touch-detectable fascia or touch-detectable membrane interface, and more particularly but not necessarily exclusively for a touchscreen device, to prevent or limit unintentional activation of the switch. The invention also relates to a method of preventing accidental activation of such a switch, and to a motor vehicle incorporating at least one electrical component activatable by such a switch.

### BACKGROUND OF THE INVENTION

Touch-screen technology now pervades all aspects of modern life, as tablet computers and touch-activatable smartphones become widespread. Such technology has been incorporated in other areas as an alternative means of control to standard mechanical or electromechanical controllers.

One such field is the automotive industry. A modern motor vehicle comprises a large number of electronically controlled components, some automatically controlled, and some requiring user input. Touch-screens can be provided on the dashboard of the vehicle, from which the user can control, for example, the audio system, climate control or navigation system of the vehicle.

Touch sensing is typically achieved by utilising a capacitive touch-screen, which is generally formed as an electrical insulator coated with an electrical conductor. When a user touches the screen, there is a resultant distortion in the electrostatic field of the screen, which can be detected and can result in an activation of an associated control function.

The nature of capacitive touch sensing does mean that it is vulnerable to false firing, that is, inadvertent activation. Stray electromagnetic fields can cause similar disturbances in the screen field, causing accidental activation, which may be caused by a user getting too close to the screen, touching it accidentally, or triggering the incorrect command.

In a motor vehicle, accidental activation can be dangerously problematic, as it can result in the driver becoming distracted as they attempt to rectify the issue, which may in turn lead to dangerous driving.

It is also an issue that current touch-screen technology requires a flat panel display, and such capacitive screens are rigid and non-deformable. This makes current technology difficult to incorporate into non-planar and/or smaller locations.

### SUMMARY OF THE INVENTION

Hence there is a desire for a switch which must be activated in multiple stages to avoid false activation or false-firing.

Accordingly, in a first aspect thereof, the invention provides a multi-stage switch for a touch-detectable device, the switch comprising: a touch-detection layer; a switch circuit substrate; an electrical contact set including a first electrical contact in communication with the touch-detection layer, and a second electrical contact in communication with the switch circuit substrate, the switch being activatable only upon detection of a touch at the touch-detection layer at or adjacent the first electrical contact and upon electrical activation of the electrical contact set.

By providing a multi-stage switch forming part of a touch screen device or including a touch-detectable fascia or touch-detectable membrane interface, it is possible to limit accidental activation of the command controlled by the switch. In order for the user to activate the switch, their touch must be detected, and sufficient force must be provided to activate an electrical contact set, either simultaneously or sequentially. Such a switch limits false-firing by, for example, the user brushing against the switch, whilst negating the need for a tactile button projecting from the screen of the touch-detectable device, which would otherwise prevent the use of swipes or similar gesture commands to control the device.

Preferably, the touch-detection layer may comprise a capacitive touch sensor. Such a sensor may be advantageously resiliently deformable.

Capacitive touch sensors are more prone to false-firing since they generally require physical contact with the user's skin in order to operate. Operation of a touch-detectable device with a finger is less accurate than when using a stylus as there is a much greater operative area. As such, the limitation of false-firing of the screen is highly beneficial to capacitive touch-detectable technology.

An electrically-insulative spacer may be provided between the touch-detection layer and the switch circuit substrate, so as to provide a separation between the first and second electrical contacts. This advantageously allows for a convenient way of creating a secondary activation stage; sufficient force must be applied by the user to bring the physically separate first and second electrical contacts into engagement to complete the switch.

Optionally, a plurality of first electrical contacts may be provided, which may be individually operable as part of a distinct switch, the touch-detection layer being capable of individual activation of each said distinct switch. Additionally or alternatively, a plurality of second electrical contacts may be provided, which may be individually operable as part of a distinct switch, the touch-detection layer being capable of individual activation of each said distinct switch.

The switch may advantageously be sub-divided such that a single multi-stage switch can control multiple, generally linked, functions. An audio player may, for example, require play, pause, rewind, fast-forward functionality and so forth, and by combining all of these features into a single multi-stage switch, the volume and weight of the switch can be reduced. This may be particularly useful in the automotive industry, wherein excess weight in a vehicle results in increased fuel consumption.

In a preferable embodiment, an upper or outer surface of the touch-detection layer may provide a user interface of the switch, which may preferably be a smooth surface. The user interface of the switch may be indicated by graphical indicia associated with the touch-detection layer.

In an ideal scenario, the touch-detection layer, being part of a touch-detectable device, has a flat graphical interface to enable the user to interact with complex gesture commands.

The switch may include a lighting element, the touch-detection layer being at least in part transparent or translucent.

By backlighting the touch-detection layer, the user interface is beneficially easier for a user to view and interact with. This increases the usability of the device into which the switch is incorporated.

Optionally, the sensitivity of the touch-detection layer may be adjustable. Furthermore, electrical contact between the first and second electrical contacts may be effected by application of a force upon the touch-detection layer, and this force may be adjustable. By adjusting the forces required to activate the switch, it is possible for the optimal balance between switch sensitivity and avoidance of false-firing can be found.

The multi-stage switch may have the first and second electrical contacts are spaced apart. A mechanical dome switch may be interposed between the first and second electrical contacts, and this may provide haptic feedback to the user through the touch-detection layer.

Haptic feedback provides the user with acknowledgement that their command has been registered, ensuring that they do not damage the touch-detection layer by over-application of force.

In one embodiment, the first and second electrical contacts may be engagable via resistive touch contact.

By providing a resistive touch contact instead of an actuatable contact set, there are fewer mechanical parts to the switch, which not only reduces the size of the switch, but also limits the number of parts which could malfunction under excessive user forces.

At least the switch circuit substrate may be formed from a flexible material. This advantageously permits the switch to be affixed to non-planar surfaces and be incorporated into contoured or curved installations, such as those typically found on the dashboards of motor vehicles.

In an optional embodiment, the switch may further comprise a secondary electrical contact set in communication with the said electrical contact set, the secondary electrical contact set being electrically activatable by application of a force upon the second electrical contact of the said electrical contact set.

By providing a secondary electrical contact set, it is possible to provide a switch which has a dual activation mode, in which application of a first, gentle pressure on the touch-detection layer activates the main electrical contact set to trigger a first function, whereas a stronger application of force urges the secondary electrical contact into engagement, which can subsequently activate a second function. This increases the usefulness of the switch for the user.

According to a second aspect of the invention, there is provided a method of preventing or inhibiting unintentional activation of a multi-stage switch, preferably in accordance with the first aspect of the invention, the method comprising the steps of: a] electrically detecting a touch of a user on the switch; and b] requiring the user to apply sufficient force to activate a mechanically operable part of the switch, the switch only activating a function upon completion of both steps a] and b].

During step a], the electrical detection of the touch of the user may be determined capacitively. Furthermore, during step b], the user may be required to supply sufficient force to push electrical contacts into physical contact, or alternatively, the user may be required to supply sufficient force to activate a resistive electrical contact.

Providing a multi-stage method of activating a touch-detectable switch, it is possible to prevent or limit the false-firing associated with capacitive touch-detectable devices, ensuring that a user's commands are more likely to be correctly recognised.

According to a third aspect of the invention, there is provided a motor vehicle having at least one electrically operable component and a multi-stage switch, preferably in accordance with the first aspect of the invention, the or each electrically operable component being activatable utilising the multi-stage switch.

By limiting the likelihood of false-firing of the switch in a motor vehicle, the probability of distraction to the driver is greatly reduced, thereby subsequently reducing the likelihood of dangerous and/or inattentive driving.

### BRIEF DESCRIPTION OF THE DRAWINGS

Preferred embodiments of the invention will now be described, by way of example only, with reference to figures of the accompanying drawings. In the figures, identical structures, elements or parts that appear in more than one figure are generally labeled with a same reference numeral in all the figures in which they appear. Dimensions of components and features shown in the figures are generally chosen for convenience and clarity of presentation and are not necessarily shown to scale. The figures are listed below.

FIG. 1 shows a cross-sectional representation of a first embodiment of a multi-stage switch in accordance with the first aspect of the invention;

FIG. 2 shows a cross-sectional representation of a second embodiment of a multi-stage switch in accordance with the first aspect of the invention;

FIG. 3 shows a cross-sectional representation of a third embodiment of a multi-stage switch in accordance with the first aspect of the invention;

FIG. 4 shows a cross-sectional representation of a fourth embodiment of a multi-stage switch in accordance with the first aspect of the invention; and

FIG. 5 shows a schematic representation of a dashboard of a motor vehicle in accordance with the third aspect of the invention.

### DETAILED DESCRIPTION OF THE PREFERRED EMBODIMENTS

Referring firstly to FIG. 1, there is shown a first embodiment of a multi-stage switch, shown globally at 10. The switch 10 may, as shown, be formed as a series of layers, and may be incorporated as part of a touch-detectable device, such as a touch-detectable fascia or other kind of touch-detectable switch interface.

The switch 10 comprises an uppermost touch-detection layer 12, positioned above and separated from a switch circuit substrate 14 by an electrically-insulative or dielectric spacer 16. Between the touch-detection layer 12 and the switch circuit substrate 14 is an electrical contact set 18, which, in the illustrated embodiment, is formed as an elongate first electrical contact 20 attached to the touch-detection layer 12 and a plurality of second electrical contacts 22 attached to the switch circuit substrate 14.

The touch-detection layer 12 is, in this embodiment, a capacitance switch circuit membrane, preferably at least partially flexible, and may be formed, for example, by coating a glass screen with a transparent conductor such as Indium Tin Oxide. However, it will be appreciated that the field of touch-detection technology incorporates numerous types of touch-screens and other kinds of touch-detectable fascias and/or membranes, including but not necessarily limited to resistive touch-screens or electronic-ink screens, and therefore the present invention should not or may not necessarily be assumed to be restricted to capacitive touch-detection.

The touch-detection layer 12 may preferably be or include a membrane having an upper or outer, user-facing, surface 24 which acts as the surface via which the user is able to interact with the switch, and a lower, internal surface 26 upon which is mounted the first electrical contact 20. By utilising an at least in part flexible membrane as or as part of the touch-detection layer 12, the upper or outer surface 24 presented to the user as a touch-interface can be non-planar in at least two dimensions and where necessary in three dimensions, allowing the switch to be incorporated in devices, such as a fascia of a vehicle, which is curved and/or flat.

It will be apparent that the first electrical contact 20 may be integrally formed with the touch-detection layer 12, if so desired. Ideally the upper surface 24 will have any user indicia, typically but not necessarily graphical, being formed within the touch-detection layer 12 itself.

In the depicted switch 10, the first electrical contact 20 is formed as a single shorting pad, an electrically-conductive, typically metallic, layer which spans a continuous area of the lower surface 26 of the touch-detection layer 12.

The switch circuit substrate 14 provides structural support to the switch 10 and may for example be a rigid circuit board, or more preferably may be a flexible printed circuit substrate. In either case, the switch circuit substrate 14 preferably also acts as a support for the circuitry connected to the switch 10, illustrated in FIG. 1 as circuit connectors 28.

The second electrical contacts 22 are here shown formed as three smaller contact pads 22a, 22b, 22c affixed to an upper, internal surface 30 of the switch circuit substrate 14. Atop each contact pad 22a, 22b, 22c is provided a printed dielectric spacer 32 which may, for example, be formed as a mechanical dome switch, and can provide haptic feedback to the user when engaging the electrical contact set 18.

The spacer 16 is provided as a layer positioned between the touch-detection layer 12 and the switch circuit substrate 14, and is of sufficient thickness so as to ensure that the first and second electrical contacts 20, 22 can be inserted there between.

The spacer 16 may be formed from an electrically-insulative plastics material, such as polyethylene terephthalate (PET), which is then connected to both the touch-detection layer 12 and the switch circuit substrate 14, or may preferably be formed from an adhesive material of uniform thickness for direct connection of the touch-detection layer 12 and the switch circuit substrate 14.

The spacer 16 in the depicted embodiment forms a void 34 between the touch-detection layer 12 and the switch circuit substrate 14, into which the electrical contact set 18 is seated such that the first and second contacts 20, 22 are spaced apart from one another. However, it is alternatively possible to provide for electrical contacts which are always in physical engagement with one another, with the electrical communication being provided for via the application of pressure by the user onto the contacts, such as that provided by a resistive contact set. It is therefore not strictly necessary for the electrical contacts to be physically displaced into engagement to complete the electrical contact set, and therefore the term electrical activation of the electrical contact set is used, and should be deemed to refer to any means by which an electrical contact set is completed.

In use, the user will touch the upper surface 24 of the switch 10 according to a user interface which may illustrate to the user the function of that particular switch. Touching the upper surface 24 of the touch-detection layer 12 will disrupt the electrostatic field within the touch-detection layer 12 which can be detected by a logic circuit associated with the switch 10. The switch 10 will not activate unless the touch-determination layer 12 has determined that the user is touching it.

However, this is not the only requirement for the switch 10 to be activated. In order to avoid false-firing, the electrical contact set 18 must also be pushed into an engaged condition to effect electrical activation. The user must supply sufficient pressure to the upper surface 24 of the touch-detection layer 12 in order to manipulate the first and second electrical contacts 20, 22 into electrical communication with one another. Only once the contact of the electrical contact set 18 has been formed and the user touch has been detected by the touch-detection layer 12 will the switch 10, as a whole, activate.

In this manner, it is therefore possible to separate the functionality of the switch into two components: firstly, an electrically operable activation, that is, detection of the touch of the user in a capacitive manner; and secondly, a mechanically operable activation, that is, engaging the electrical contact set.

The separation of the second electrical contact 22 into electrical contact pads 22a, 22b, 22c allows the multi-stage switch 10 to provide for multiple switches therein. For example, the depicted arrangement could be configured to control different aspects of a music player, with the contact pads respectively controlling rewind 22a, play/pause 22b and fast-forward 22c functionality.

The force required to activate the switch 10 can be readily altered, for example, by changing the flexibility or thickness of the touch-detection layer 12, the separation between the first and second electrical contacts 20, 22 if a spaced-apart electrical contact set 18 is provided, or the resistance required to electrically activate the electrical contact set if a resistive contact set is provided. This advantageously allows the manufacturer to fine-tune the sensitivity of the switch 10 to best avoid false-firing. Additionally, it is possible to alter the logic of the underlying logic circuit associated with the touch-detection layer 12 to alter the threshold for detecting the user's touch, thereby making the switch 10 more adjustable.

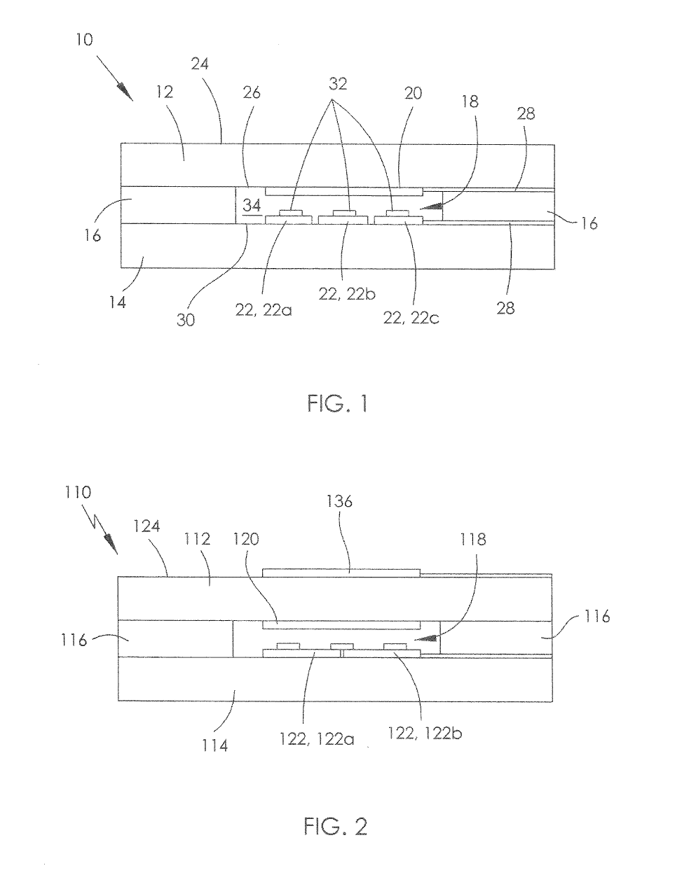

Alternative embodiments of the switch are possible, and one such alternative is shown globally in FIG. 2 as 110. Identical or similar components to those of the first embodiment of the switch 10 are referred to using identical or similar references, and therefore further detailed description is omitted for brevity.

On the upper surface 124 of the touch-detection layer 112 in the second embodiment of the switch 110 is provided a tactile pad 136. This enables the user to more accurately determine which particular switch function is being activated by their touch.

The embodiment shown also illustrates that the electrical contact set 118 may take a different form; in this instance, the first electrical contact 120 is still a shorting pad, whereas the second electrical contact 122 is formed as only two contact pads 122a, 122b, affixed to the switch circuit substrate 114 between the spacer 116.

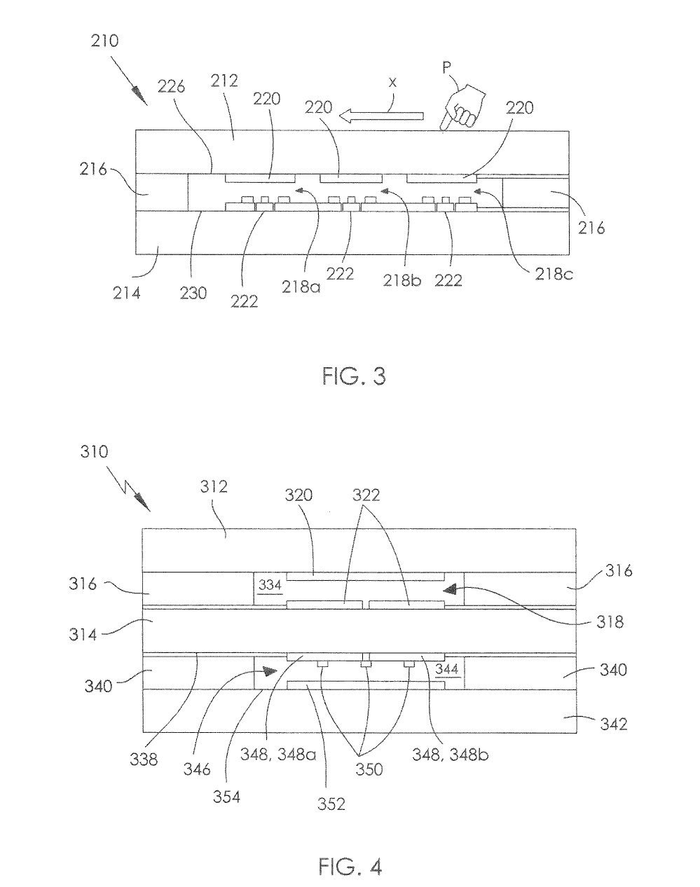

A third embodiment of the switch 210 is illustrated in FIG. 3, in which a plurality of both first and second electrical contacts 220, 222 is provided. Three first electrical contacts 220 are shown on the lower surface 226 of the touch-detection layer 212 between the spacer 216, with three second electrical contacts 222 on the upper surface 230 of the switch circuit substrate 214.

The advantage of providing distinct first electrical contacts 220 is that a user is able to provide a sliding or swiping motion across the upper surface of the touch-determination layer 212 so as to provide more specialised commands via the touch-determination layer. The embodiment shown, having three discrete switches allows the formation of five switch combinations with the electrical contact sets closing and opening as the user slides his finger across the surface, namely, 218a, 218a+b, 218b, 218b+c and 218c. Of course, any number of discrete electrical contact sets may be formed, as requirements dictate.

A processor associated with the switch 210 can determine one or more motions X performed by the user P based on the timing sequence registered as the respective electrical contact sets 218a, 218b, 218c are brought into engagement.

A more complicated embodiment of the invention is shown in FIG. 4, shown globally as 310, and which permits a more nuanced activation sequence depending on whether a small or large pressure is applied to the touch-determination layer 312 of the switch 310.

As in the previous embodiments, there is provided a touch-detection layer 312 which is spaced apart from a switch circuit substrate 314 by a spacer 316, with an electrical contact set 318 positioned there between in the void 334 created.

However, attached to a lower surface 338 of the switch circuit substrate 314 is a further spacer 340, separating the switch circuit substrate 314 from a secondary shorting membrane 342. The further spacer 340 defines a further void 344 within which is positioned a secondary electrical contact set 346.

The secondary electrical contact set 346 comprises a further first electrical contact 348 affixed to the lower surface 338 of the switch circuit substrate 314. In this embodiment, the further first electrical contact 348 is formed as two contact pads 348a, 348b each of which includes a printed dielectric spacer 350.

A further second electrical contact 352 is also provided, affixed to an upper surface 354 of the secondary shorting membrane 342, and in the present embodiment is formed as a singular shorting pad.

This dual-layer switch 310 allows for first and second sequential firing stages to be created. A user can touch the touch-detection layer 312 gently in the first instance to select a first function. The touch will be detected, and the user will also apply sufficient pressure to engage the first and second electrical contacts 320, 322 of the first electrical contact set 318, thereby completing the first firing stage of the switch 310.

However, a greater application of pressure upon the touch-detection layer 312 will result in a displacement of the switch circuit substrate 314. This will push the further first electrical contact 348 into electrical communication with the further second electrical contact 352, thereby engaging the secondary electrical contact set 346, and as the touch-detection layer 312 is already activated, secondary functionality can be activated.

This secondary functionality, or indeed, entirely different functionality, advantageously reduces the number of inputs which must be presented to the user on the touch-detection layer 312, allowing the manufacturer to reduce the overall size and weight of the device incorporating the switch 310.

It will also be appreciated that further layers may be included allowing additional functionality to be achieved by further pressure being applied to active further electrical contact sets.

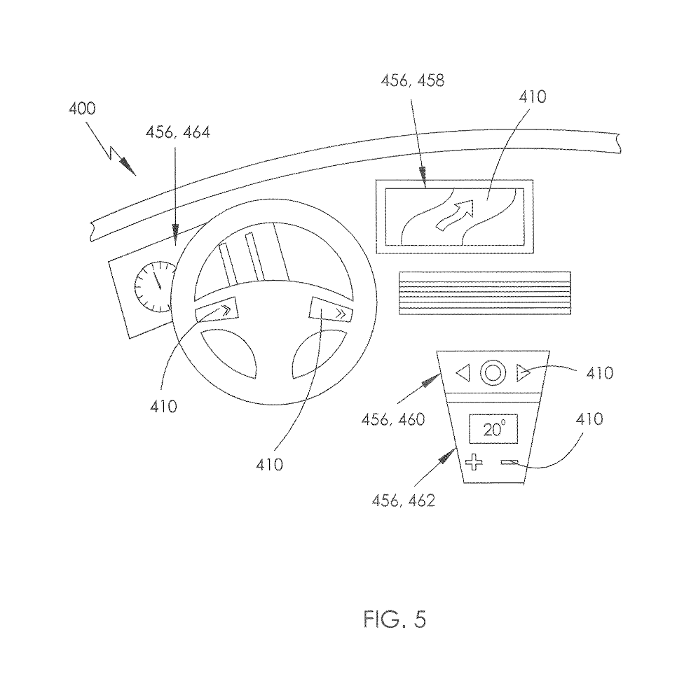

In FIG. 5 is shown a stylised view of how such switches may be integrated into a motor vehicle, the dashboard 400 of which is shown globally. Various different indicators within the vehicle may be presented on display screens 456, for instance, the accelerometer, or temperature gauges.

However, there may also be a number of user interfaces 410 into which the driver or passenger may input commands, and these user interfaces may employ multi-stage switches as hereinbefore described. Applicable user interfaces 410 could be, but are not limited to, the navigation system 458, the audio system 460, the climate control 462 of the vehicle, or the dashboard display 464.

By providing these user-interfaces 410 with multi-stage switches, the person activating the tools can be certain that there will not be any incidences of false-firing, in which the user accidentally and/or unintentionally activates one or other control.

Whilst the above-described switch has primarily been described in terms of a touch-screen for a motor vehicle, it will be appreciated that such multi-stage switch technology could readily be applied to all fields in which a touch-detectable fascia or touch-detectable, preferably flexible, membrane interface may be utilised.

Furthermore, the electrical contacts of the variously described electrical contact sets are shown in many different embodiments, such as single shorting pads, multiple contact pads, and with and without dielectric spacers. It will be appreciated that any combination of electrical contact form could be provided for each electrical contact, depending upon its function and the above-described contacts should not be considered to be an exhaustive list.

Whilst not depicted in any of the hereinbefore described embodiments, one of the advantages of using a touch-detection layer is that it generally forms part of a display screen as part of the user interface of the device. As such, the touch-detection layer is generally at least in part transparent or translucent. It is therefore possible to provide a lighting element within the switch, such as an LED assembly, which illuminates the display and/or user interface, helping the user to quickly identify the functionality of the switch.

It is therefore possible to provide a multi-stage switch which comprises a touch-detection layer for detecting the touch of a user, and an electrical contact set which is activatable under the application of pressure from the user. In order for the switch to be activated, the electrical contact set must be engaged in addition to the user's touch having been detected. This advantageously limits false-firing of the switch, wherein the switch is unintentionally activated.

In the description and claims of the present application, each of the verbs “comprise”, “include”, “contain” and “have”, and variations thereof, are used in an inclusive sense, to specify the presence of the stated item or feature but do not preclude the presence of additional items or features.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

The embodiments described above are provided by way of example only, and various other modifications will be apparent to persons skilled in the field without departing from the scope of the invention as defined by the appended claims.

1. A multi-stage switch for a touch-detectable device, the switch comprising: a touch-detection layer; a switch circuit substrate; an electrical contact set including a first electrical contact in communication with the touch-detection layer, and a second electrical contact in communication with the switch circuit substrate, the switch being activatable only upon detection of a touch at the touch-detection layer at or adjacent the first electrical contact and upon electrical activation of the electrical contact set.

2. The multi-stage switch of claim 1, wherein the touch-detection layer comprises a capacitive touch sensor.

3. The multi-stage switch of claim 1, wherein the touch-detection layer is resiliently deformable.

4. The multi-stage switch of claim 1, wherein an electrically-insulative spacer is provided between the touch-detection layer and the switch circuit substrate.

5. The multi-stage switch of claim 1, wherein a plurality of first electrical contacts is provided.

6. The multi-stage switch of claim 5, wherein each of the plurality of first electrical contacts is individually operable as part of a distinct switch, the touch-detection layer being capable of individual activation of each said distinct switch.

7. The multi-stage switch of claim 1, wherein a plurality of second electrical contacts is provided.

8. The multi-stage switch of claim 7, wherein each of the plurality of second electrical contacts is individually operable as part of a distinct switch, the touch-detection layer being capable of individual activation of each said distinct switch.

9. The multi-stage switch of claim 1, wherein an upper surface of the touch-detection layer provides a user interface of the switch.

10. The multi-stage switch of claim 9, wherein the upper surface of the touch-detection layer is a smooth surface.

11. The multi-stage switch of claim 9, wherein the user interface of the switch is indicated by graphical indicia associated with the touch-detection layer.

12. The multi-stage switch of claim 1, wherein the switch includes a lighting element, the touch-detection layer being at least in part transparent or translucent.

13. The multi-stage switch of claim 1, wherein the sensitivity of the touch-detection layer is adjustable.

14. The multi-stage switch of claim 1, wherein electrical contact between the first and second electrical contacts is effected by application of a force upon the touch-detection layer.

15. The multi-stage switch of claim 14, wherein the force required to electrically activate the electrical contact set is adjustable.

16. The multi-stage switch of claim 1, wherein the first and second electrical contacts are spaced apart.

17. The multi-stage switch of claim 16, wherein a mechanical dome switch is interposed between the first and second electrical contacts.

18. The multi-stage switch of claim 17, wherein the mechanical dome switch provides haptic feedback to the user through the touch-detection layer.

19. The multi-stage switch of claim 1, wherein the first and second electrical contacts are engagable via resistive touch contact.

20. The multi-stage switch of claim 1, wherein at least the switch circuit substrate is formed from a flexible material.

21. The multi-stage switch of claim 1, further comprising a secondary electrical contact set in communication with the said electrical contact set, the secondary electrical contact set being electrically activatable by application of a force upon the second electrical contact of the said electrical contact set.

22. The multi-stage switch of claim 1, formed as part of a touchscreen device.

23. A method of preventing or inhibiting unintentional activation of the multi-stage switch of claim 1, the method comprising the steps of: a] electrically detecting a touch of a user on the switch; and b] requiring the user to apply sufficient force to activate a mechanically operable part of the switch, the switch only activating a function upon completion of both steps a] and b].

24. The method of claim 23, wherein during step a], the electrical detection of the touch of the user is determined capacitively.

25. The method of claim 23, wherein during step b], the user must supply sufficient force to push electrical contacts into physical contact.

26. The method of claim 23, wherein during step b], the user must supply sufficient force to activate a resistive electrical contact.

27. A motor vehicle having at least one electrically operable component and the multi-stage switch of claim 1, wherein the switch is arranged to activate the or each electrically operable component.
